(19) United States
(12) Patent Application Publication
(10) Pub. No.: US 2004/0222460 A1
(43) Pub. Date: Nov. 11, 2004

(54) [NON-VOLATILE MEMORY DEVICE STRUCTURE]

(76) Inventor: Chun-Jung Lin, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,756

(22) Filed: May 6, 2003

(51) Int. Cl. H01L 29/76

(52) U.S. Cl. 257/331

(57) ABSTRACT

A non-volatile memory device structure, having a plurality of gates, a plurality of bit lines and a plurality of word lines. The gates are formed in a substrate. The bit lines are between the gates and formed of a buried diffusion line and an elevated conductor layer formed on the buried diffusion line. The word lines are substantially perpendicular to the bit lines over the gates and across the elevated conductor layer of the bit lines. The sidewall of the elevated conductor layer of the bit lines further has a first spacer, while the sidewall of the word lines has a second spacer.

### BACKGROUND OF INVENTION

1. Field of the Invention

The invention relates in general to a memory device structure, and more particularly, to a non-volatile memory device structure.

2. Related Art of the Invention

Contact windows have been frequently formed for providing interconnection of multi-layer circuit structures in VLSI and ULSI. In the development of integrated circuits, as the device dimension approaches the sub-micron stage, the conventional contact windows are gradually becoming incapable of providing effective interconnection, and are further limiting device performance in various ways. When the areas of contact windows are reduced in response to device shrinkage, the resistance thereof is consequently increased. Particularly, when the diffusion region is reduced as the device scale decreases, the alignment between the contact window and the diffusion region becomes a difficult task. To avoid process problems and device failure caused by misalignment between the contact window and the diffusion region, a reserved region that degrades the device integration is typically required, or alternatively, the area of the diffusion region has to be increased. The enlarged diffusion region often increases the junction capacitance between the substrate and the diffusion region. As a result, the device speed is reduced.

### SUMMARY OF INVENTION

The present invention provides a non-volatile memory device structure that can overcome the misalignment problem of contact windows.

The present invention further provides a non-volatile memory device structure that enlarges the process window of photolithography process.

In the non-volatile memory device structure provided by the present invention, the buried diffusion line or region (BD line) is elevated to maintain the shallow junction to top surface of a silicon substrate in which the buried diffusion line is formed.

In the above non-volatile memory device structure, the sheet resistance of the bit line is reduced.

In one embodiment, the non-volatile memory device structure comprises a plurality of gates, a plurality of bit lines and a plurality of word lines. The gates are formed in a substrate. The bit lines are between the gates and formed of a buried diffusion line or region and an elevated conductor line formed on the buried diffusion line or region, wherein the elevated conductor layer is electrically connected to the buried diffusion line or region and is surrounded by a spacer. The word lines are substantially perpendicular to the bit lines over the gates and across the elevated conductor layer of the bit lines.

The present invention further provides a non-volatile memory device structure, including a memory cell with a gate and a buried source/drain region, a bit line, a word line and spacers located at sidewalls of the bit line and the word line. The word line and the gate are made of polysilicon, for example. In addition, an inter-layer dielectric (ILD) is formed over the substrate to cover the bit line and the word line. The allocations of the above devices are as follows. The gate of the memory cell is formed on the substrate, the buried source/drain region is formed under the top surface of the substrate at a side of the gate, the bit line is coupled to the buried source/drain region, and the bit line is coupled to the gate. The material for forming the spacers of the bit line, the word line and the inter-layer dielectric includes material with high selectivity. For example, the inter-layer dielectric can be made of BPSG, while the spacers can be made of high-temperature oxide or silicon nitride.

As the polysilicon elevated conductor layer is formed to elevate the buried diffusion line, not only is the shallow junction of the buried diffusion line underlying the top surface of the silicon substrate maintained, but the sheet resistance of the bit line is also the reduced. In addition, the bit line comprises a conductor layer protruding from the substrate, such that the top surface of the bit line is higher than the conventional structure after forming the spacer of the elevated conductor layer of the bit line. Therefore, the bit line is exposed faster during etching process of the contact window. Consequently, the misalignment problem of the contact window is resolved, and the process window of the photolithography is widened.

### BRIEF DESCRIPTION OF DRAWINGS

These, as well as other features of the present invention, will become more apparent upon reference to the drawings.

FIG. 1 shows a top view of a non-volatile memory device in one embodiment of the present invention.

FIG. 2 shows a perspective view of the non-volatile memory device as shown in FIG. 1.

FIGS. 3A to 3D are cross-sectional views of the non-volatile memory device as shown in FIG. 2 along III-III′ in various processing stages.

FIGS. 4A to 4C show cross-sectional views of the non-volatile memory device as shown in FIG. 2 along IV-IV′ in various processing stages.

FIG. 5 shows the schematic structure of the non-volatile memory device as shown in FIG. 2 along V-V′.

### DETAILED DESCRIPTION

In the following description, the illustrated fabrication process and structure are not the complete process of an integrated circuit. The present invention can be implemented by various fabrication techniques of integrated circuits, while only the technique essential for understanding the present invention is provided. The accompanied drawings are in schematic and simplified as a reference to the detailed description of the present invention, and the actual structure of the memory device is more complex.

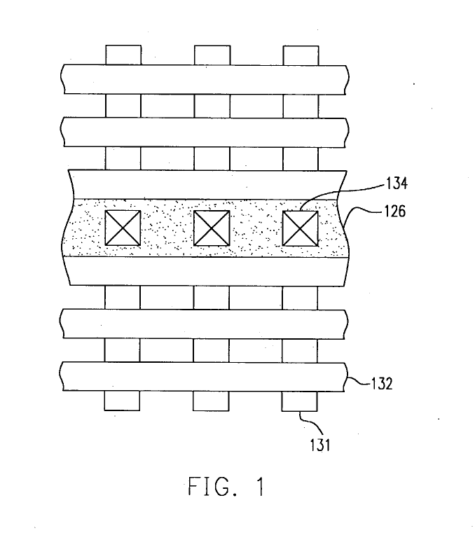

FIG. 1 shows the top view of a non-volatile device in one embodiment of the present invention. Referring to FIG. 1, the structure comprises several gates, several bit lines 131 and several word lines 132. Each bit line 131 comprises a buried diffusion line and an elevated conductor layer formed on the buried diffusion line. The gates are located under the word lines 132 between the elevated conductor layers of the bit lines 131. In addition, as shown in FIG. 1, a spacer 126 is formed on the sidewall 132 of each word line 132. To simplify the drawing, only a part of the spacers 126 between two word lines 132 are illustrated in FIG. 1. The spacers 126 can be used as an etch stop to prevent causing process problems and device failure by etching the contact window.

The structure provided by the present invention is further described as follows.

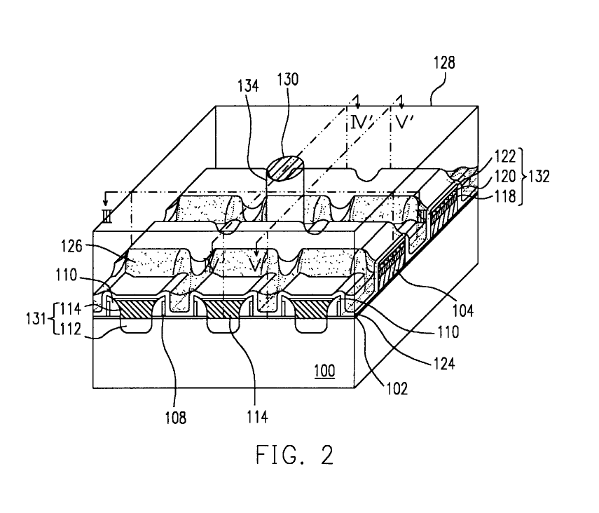

FIG. 2 shows a perspective view of the non-volatile memory device. In FIG. 2, the structure comprises gates 104 formed on a substrate 100, bit lines 131 between the gates 104, and word lines 132 perpendicular to the bit lines 131 and covering the gates 104 and a part of the bit lines 131. The material of the gates 104 includes polysilicon, for example, and the thickness of the gates 104 is preferably 1500 angstroms. The bit lines 131 include a continuous buried diffusion line or a series of discrete diffusion regions 112 and an elevated conductor layer 114 on the buried diffusion line 112. The material of the elevated conductor layer 114 is polysilicon, for example. The formation of the elevated conductor layer 114 elevates the bit lines 131, such that the shallow junction of the buried diffusion line 112 under the substrate 100 is maintained, and the sheet resistance of the bit lines 131 is reduced. In addition, spacers 126 may be formed on sidewalls of the elevated conductor layer 114, such that the bit line 131 including the elevated conductor layer 114 outstanding from the substrate 100 is easier and faster to expose while etching the contact window 134 compared to the conventional structure. Meanwhile, the peripheral devices around the contact window 134 are protected by the spacers 126, such that the misalignment problem of the contact window is resolved.

The word lines 132 are substantially perpendicular to the bit lines 131. For example, the word lines 132 may include conductor layers 118 and 120. The conductor layer 118 is located above the gates 104 and across the elevated conductor layer 114 of the bit lines 131. The conductor layer 118 is preferably a polysilicon layer, while the other conductor layer 120 is preferably made of silicide to reduce the resistance of the word lines 132. In addition, the word lines 132 may further comprise a dielectric layer 122 on top of the conductor layer 120. The material of the conductor layer 120 is silicon nitride or silicon dioxide, for example.

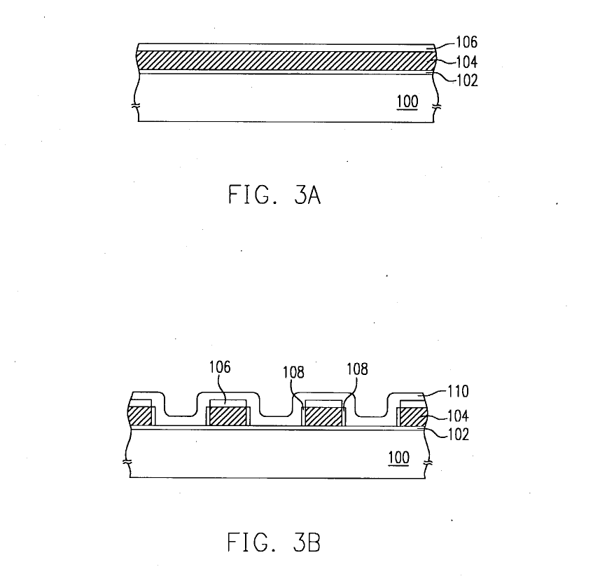

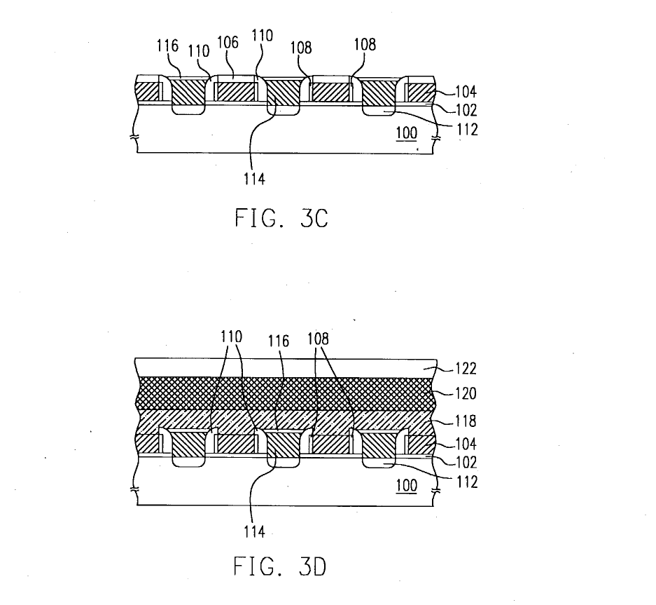

Referring to FIG. 2 and FIG. 3D that illustrates the cross-sectional view along the line III-III″ of FIG. 2, a first spacer 110 is formed on the sidewall of the elevated conductor layer 114. The material for forming the first spacer 110 includes high-temperature oxide (HTO), for example. Further, an oxide layer 116 is formed between the elevated conductor layer 114 of the bit lines 131 and the conductor layer 118 of the word lines 132 for isolating the bit lines 131 and the word lines 132.

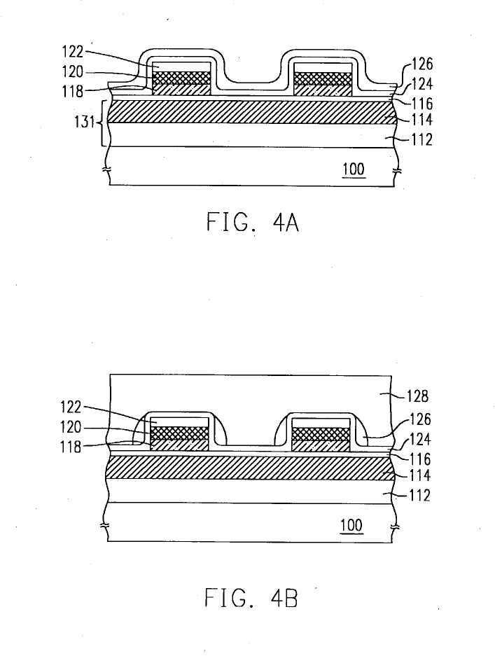

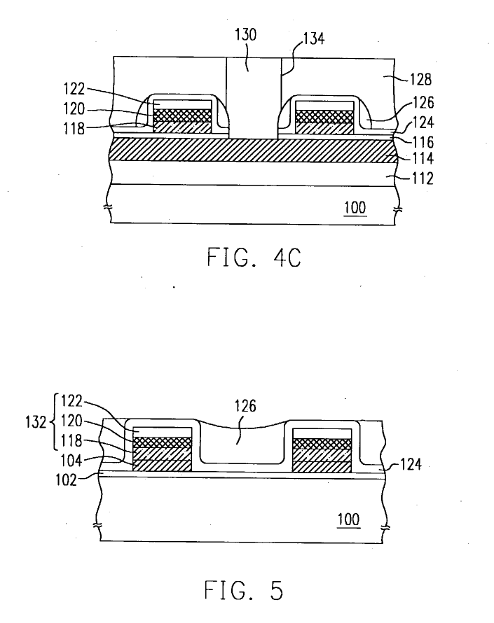

Referring to FIG. 2 and FIG. 4C, which illustrates the cross sectional view along the line IV-IV″ of FIG. 2, a second spacer 126 is formed on the sidewall of the word lines 132. The material of the spacer 126 includes silicon nitride, for example. The spacer 126 is operative to prevent damaging the device should misalignment occur during the subsequent etching process of the contact window 134. Between the second spacer 126 and the sidewall of the word lines 132, a dielectric layer 124 covering the elevated conductor layer 114 of the bit lines 131 and the substrate 100 is further formed as a liner and etch stop of the dielectric layer 124. The substrate 100 may further include an inter-layer dielectric 128 covering the word lines 132 and the bit lines 131, and penetrating therethrough include a contact window 130 connected to the elevated conductor layer 114 of the bit lines 131. The inter-layer dielectric 128 and the spacer 126 are made of materials with high selectivity, such that the peripheral devices of the contact window 134 are protected while etching the inter-layer dielectric 128. For example, the material of the inter-layer dielectric 128 is BPSG, while the material of the spacer 126 is silicon nitride.

The method for forming the above structure is described as follows. FIGS. 3A to 3D show the cross-sectional views of the structure along III-III′ in various process stages, FIGS. 4A to 4C are cross-sectional views of the structure along IV-IV′ in various process stages, and FIG. 5 shows the cross-sectional view along the V-V′.

Referring to FIG. 3A, a substrate 100 is provided. The substrate 100 includes a dielectric layer 102, a conductor layer 104 formed on the dielectric layer 102, and a dielectric layer formed on the conductor layer 104 thereon.

Referring to FIG. 3B, a conventional photolithography and etching process is performed to transfer the pattern of a buried diffusion line into the dielectric layer 106 and the conductor layer 104 to expose the dielectric layer 102, so as to form the gates 104. An oxide layer 108 is formed on the sidewalls of the conductor layers 104 using conventional wet or dry oxidation. A dielectric layer 110 is then formed to cover the above structure over the substrate 100.

Referring to FIG. 3C, the dielectric layer 110 is etched using conventional dry etch back to form the spacer 110, so as to expose the substrate 100. A buried diffusion line 112 is then formed in the substrate 100. An elevated conductor layer 114 is then formed and etched back using the conventional etching process, such that the elevated conductor layer 114 has a top surface lower than the top surface of the spacer 110 after being etched back.

In FIG. 3D, the dielectric layer 106 is removed, and a conductor layer 118 is formed over the structure formed on the substrate 100. The conductor layer 118 includes a polysilicon layer, for example. Another conductor layer 120 is further formed on the conductor layer 118. The material of the conductor layer 120 includes silicide, for example. A dielectric layer 120 is formed on the conductor layer 120. The material of the dielectric layer 120 includes silicon nitride or silicon dioxide, for example. The subsequent processes are shown in FIGS. 4A to 4C.

In FIG. 4A, a conventional photolithography and etching process is performed to etch the dielectric layer 122, and the conductor layers 120 and 118 to expose the oxide layer 116, so as to etch the conductor layer 104 (Referring to FIG. 2) in the region not used for forming the bit lines 131. The word lines 132 as shown in FIG. 2 are thus formed. As shown in FIG. 4A, the word lines comprise the dielectric layer 122, the conductor layers 120 and 118. Another dielectric layer 124 is formed to cover the structure formed on the substrate as shown in FIG. 4A. The dielectric layer 124 includes high-temperature oxide. Another dielectric layer 126 is formed on the dielectric layer 124. The material of the dielectric layer 126 includes silicon, but is not limited thereto.

Referring to FIG. 4B, the dielectric layer 126 is etched using conventional dry etch back process to form the spacer 126 on the sidewall of the word lines 132. An inter-layer dielectric 128 is formed by chemical vapor deposition on the structure formed on the substrate 100 as shown in FIG. 4B. The materials for the inter-layer dielectric 128 and the spacer 126 require high selectivity, such that the peripheral device will not be damaged during the etching process of the inter-layer dielectric 128. For example, when silicon nitride is selected for forming the spacer 126, the material of the inter-layer dielectric 128 includes BPSG. The inter-layer dielectric 128 can then be densified by rapid thermal process.

In FIG. 4C, the contact window 134 as shown in FIG. 1 is formed by performing conventional photolithography and etching process on the inter-layer dielectric 128, the dielectric layer 124 and the oxide layer 116. The spacer 126 is operative as an etch stop to prevent causing process problems and device failure by etching the contact window 134. A conductive material such as aluminum is then filled in the contact window 134 to form a contact 130.

FIG. 5 shows the schematic structure along the line V-V″ in FIG. 2. As shown in FIG. 5, a dielectric layer 102 is formed between the substrate 100 and the word lines 132 for isolation between the substrate 100 and the word lines 132.

According to the above, the present invention is characterized in elevating the buried diffusion line by formation of a polysilicon conductor layer. Thereby, the shallow junction of the buried diffusion line in the silicon substrate is maintained, and the sheet resistance of the bit line is reduced. In addition, as the bit line is elevated from the substrate, by forming the spacers on sidewalls of the word lines and the elevated conductor layer of the bit lines, the bit line is exposed faster while etching the contact window. As a result, the misalignment problem of the contact window is overcome, and the process window for photolithography process is broadened.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

1. A non-volatile memory device structure, comprising at least:
a plurality of gates, located on a substrate;
a plurality of bit lines, located between the gates, each further comprising:
a buried diffusion region between the gates and under a top surface of the substrate; and
an elevated conductor layer between the gates, wherein said elevated conductor layer is electrically connected to said buried diffusion region and is surrounded by a first spacer; and
a plurality of word lines, substantially perpendicular to the bit lines over the gates and across the elevated conductor layers.

2. The structure according to claim 1, wherein the elevated conductor layers comprise polysilicon layers.

3. The structure according to claim 1, wherein the first spacers include high-temperature oxide layers.

4. The structure according to claim 1, wherein the gates comprise a polysilicon layer.

5. The structure according to claim 4, wherein the polysilicon layer has a thickness of about 1500 angstroms.

6. The structure according to claim 1, wherein the word lines further comprise:
a polysilicon layer; and
a silicide layer formed on the polysilicon layer.

7. The structure according to claim 1, further comprising a second spacer formed on the sidewall of each word line.

8. The structure according to claim 7, wherein the second spacers include a silicon nitride layer.

9. The structure according to claim 7, further comprising:
an inter-layer dielectric, covering the word lines and the bit lines; and
a contact window, penetrating through the inter-layer dielectric to connect the elevated conductor layer.

10. The structure according to claim 9, wherein the materials of the inter-layer dielectric and the second spacers have high selectivity.

11. A non-volatile memory device structure, comprising at least:
a plurality of memory cells, each memory cell comprising:
a gate formed on a substrate; and
a buried source/drain region formed under a top surface of the substrate next to the gate;
a plurality of bit lines, formed on the substrate and coupled to the buried source/drain of each memory cell;
a plurality of word lines, substantially perpendicular to the bit lines, the word lines being coupled to the bit lines and the gate of each memory cell;
a plurality of spacers, located on sidewalls of the bit lines and the word lines; and
an inter-layer dielectric formed over the substrate to cover the bit lines and the word lines, wherein the inter-layer dielectric and the spacers are made of high selectivity materials.

12. The structure according to claim 11, wherein the bit lines comprise a polysilicon layer.

13. The structure according to claim 11, further comprising a contact window penetrating through the inter-layer dielectric to coupled to the bit lines.

14. The structure according to claim 11, wherein the material for forming the spacers include high-temperature oxide or silicon nitride.

15. The structure according to claim 14, wherein the material for forming the inter-layer dielectric includes BPSG.

16. The structure according to claim 11, wherein the gates include a polysilicon layer.
